(19) United States
(12) Patent Application Publication
(10) Pub. No.: US 2024/0237552 A1
(43) Pub. Date: Jul. 11, 2024

(54) MAGNETIC METAMATERIAL, SPIN CURRENT CONTROL APPARATUS, AND SPIN CURRENT CONTROL METHOD

(71) Applicants: TOHOKU UNIVERSITY, Sendai-shi, Miyagi (JP); National University Corporation Tokai National Higher Education and Research System, Nagoya-shi, Aichi (JP)

(72) Inventors: Masakazu MATSUBARA, Sendai-shi (JP); Takeshi KATO, Nagoya-shi (JP)

(21) Appl. No.: 18/559,624

(22) PCT Filed: Apr. 20, 2022
(86) PCT No.: PCT/JP2022/018259

§ 371 Date: Nov. 8, 2023

(30) Foreign Application Priority Data
May 14, 2021 (JP) 2021-082127

(51) Int. Cl. H10N 50/85; H10N 50/01; H10N 50/10

(52) U.S. Cl. CPC H10N 50/85; H10N 50/01; H10N 50/10

(57) ABSTRACT

This magnetic metamaterial includes a perpendicularly magnetized film that is isotropic with respect to light, the perpendicularly magnetized film has a plurality of unit structures periodically arranged in an in-plane direction, and each of the plurality of unit structures has a size equal to or less than a wavelength of irradiated light and has three-fold rotational symmetry.

The present invention relates to a magnetic metamaterial, a spin current control apparatus, and a spin current control method. This application is a national phase entry of International Patent Application No. PCT/JP2022/018259, filed Apr. 20, 2022, which, in turn, claims priority based on Japanese Patent Application No. 2021-082127 filed in Japan on May 14, 2021, the contents of both of which are incorporated herein.

### TECHNICAL FIELD

### Background Art

Attention has been focused on spintronics in recent years. Spintronics engineeringly uses not only the degree of freedom of charge but also the degree of freedom of spin that electrons in solids have. Spintronics is responsible for the achievement of new devices with functions and capabilities that could not be achieved with electronics that utilize only the degree of freedom of charge.

A spin current is one element used in spintronics. The spin current is the difference between the currents of spin-up electrons and spin-down electrons and is represented by J_{S}=J_{↑}−J_{↓}. J_{S} represents the spin current, J_{↑} represents the current of spin-up electrons, and J_{↓} represents the current of spin-down electrons. For example, Patent Document 1 describes that when a magnetic material is irradiated with microwaves, a spin current is generated due to the spin pumping effect.

### CITATION LIST

### Patent Literature

Patent Document 1: JP 2014-086448 A

### SUMMARY OF THE INVENTION

### Technical Problem

Spin currents can also be generated by methods other than the spin pumping effect shown in Patent Document 1. Spin currents are also generated, for example, by the spin Hall effect caused by an electric current, the spin Seebeck effect caused by a heat flow, the plasmonic spin pumping effect using light, or the circular photogalvanic effect. However, no matter which method is used, it is difficult to freely control the direction and magnitude in which a spin current is generated.

The present invention has been made in view of the above problems and it is an object of the present invention to provide a magnetic metamaterial, a spin current control apparatus, and a spin current control method that can control the direction and magnitude of a spin current.

### Means for Solving the Problem

The present invention provides the following means to solve the above problems.

(1) A magnetic metamaterial according to a first aspect includes a perpendicularly magnetized film that is isotropic with respect to light. The perpendicularly magnetized film has a plurality of unit structures periodically arranged in an in-plane direction, and each of the plurality of unit structures has a size equal to or less than a wavelength of irradiated light and has three-fold rotational symmetry.

(2) In the magnetic metamaterial according to the above aspect, the perpendicularly magnetized film may have a plurality of openings forming the plurality of unit structures.

(3) In the magnetic metamaterial according to the above aspect, each of the plurality of openings may be equilaterally triangular.

(4) A spin current control apparatus according to a second aspect includes the magnetic metamaterial according to the above aspect; and a light irradiation unit that irradiates the magnetic metamaterial with light. The light irradiation unit can control an ellipticity angle and an azimuth angle of light irradiating the magnetic metamaterial.

(5) A method of controlling a spin current according to a third aspect includes irradiating a magnetic metamaterial with light whose ellipticity angle and azimuth angle are controlled. The magnetic metamaterial includes a perpendicularly magnetized film that is isotropic with respect to light, the perpendicularly magnetized film has a plurality of unit structures periodically arranged in an in-plane direction, and each of the plurality of unit structures has a size equal to or less than a wavelength of irradiated light and has three-fold rotational symmetry.

### Effects of the Invention

The magnetic metamaterial, the spin current control apparatus, and the spin current control method according to the above aspects can control the direction and magnitude of a spin current.

### BRIEF DESCRIPTION OF DRAWINGS

FIG. 1 is a perspective view of a spin current control apparatus according to a first embodiment.

FIG. 2 is a perspective view of a magnetic metamaterial according to the first embodiment.

FIG. 3 is a plan view of the magnetic metamaterial according to the first embodiment.

FIG. 4 is a plan view of a magnetic metamaterial according to a modification.

FIG. 5 is an image diagram of an experimental system according to a first example.

FIG. 6 shows the response characteristics of a spin current generated after a magnetic metamaterial was irradiated with laser light in the first example.

FIG. 7 shows the results of changing the intensity of the laser light with which the magnetic metamaterial was irradiated in the first example.

FIG. 8 shows the results of measuring the influence on the spin current when changing the magnetic field applied to the magnetic metamaterial in the first example.

FIG. 9 shows the results of measuring the direction of magnetization of a perpendicularly magnetized film using the Faraday effect in the first example.

FIG. 10 is a diagram comparing a magnetization curve of a planar Co/Pt multilayer film in which a plurality of openings had not yet been formed with a magnetization curve of the magnetic metamaterial (MM).

FIG. 11 shows the results of measuring the wavelength dependence of the transmittance (T), reflectance (R), and absorption (A) of the magnetic metamaterial.

FIG. 12 shows the results of measuring the dependence of the magnitude of a spin current on the wavelength of irradiated light in the experimental system of the first example.

FIG. 13 is an image diagram of an experimental system according to a second example.

FIG. 14 shows the results of changing an azimuth angle φ_{ω} of light with which the magnetic metamaterial was irradiated in the experimental system according to the second example.

FIG. 15 is an image diagram of an experimental system according to a third example.

FIG. 16 shows the results of measuring the x and y components (J_{s,x}, J_{s,x}) of the magnitude of the spin current when changing the azimuth angle φ_{ω} of light with which an optical element was irradiated in the experimental system according to the third example.

FIG. 17 is a diagram obtained by replacing the results of FIG. 16 with the relationship between an ellipticity angle ε_{ω} and the magnitude (|Jₛ|) of the spin current.

### DESCRIPTION OF EMBODIMENTS

Hereinafter, the present embodiment will be described in detail with appropriate reference to the drawings. In the drawings used in the following description, to make features of the present invention easy to understand, portions corresponding to the features are sometimes shown enlarged for the sake of convenience and the dimensional ratios and the like of components may differ from the actual ones. Materials, dimensions, and the like exemplified in the following description are examples, to which the present invention is not limited, and can be appropriately modified and implemented without departing from the spirit of the invention.

First, directions will be defined. One direction in a plane in which a magnetic metamaterial 10 extends is defined as an x direction and a direction orthogonal to the x direction is defined as ay direction. A direction orthogonal to the xy plane is defined as a z direction.

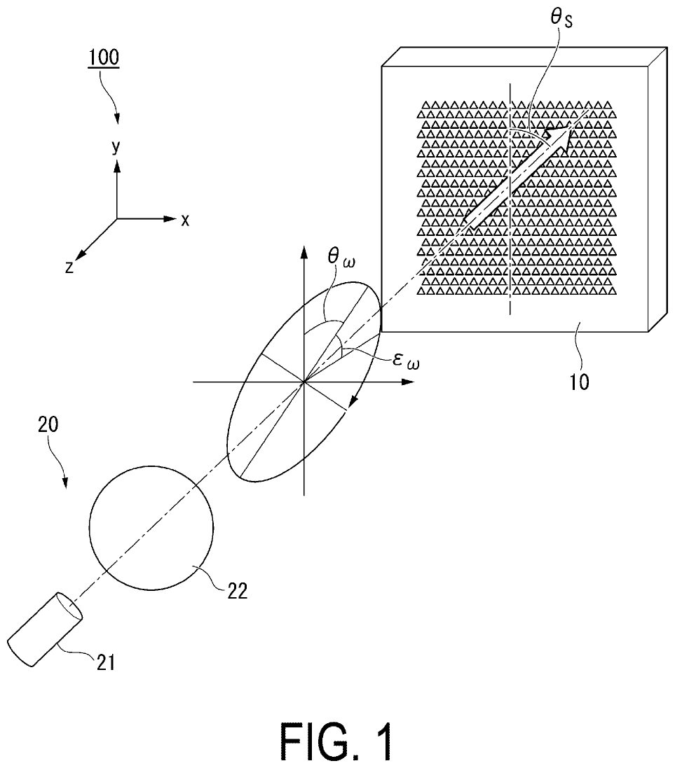

FIG. 1 is a perspective view of a spin current control apparatus 100 according to a first embodiment. The spin current control apparatus 100 includes a magnetic metamaterial 10 and a light irradiation unit 20. A magnetic metamaterial may also be called a magneto metamaterial or a magnetized metamaterial.

The light irradiation unit 20 irradiates the magnetic metamaterial 10 with light. The light irradiation unit 20 irradiates the magnetic metamaterial 10 with light, for example, in the z direction. The light irradiation unit 20 can control an ellipticity angle ε_{ω} and an azimuth angle θ_{ω} of the light with which the magnetic metamaterial 10 is irradiated. The light irradiation unit 20 includes, for example, a light source 21 and an optical element 22.

The light source 21 is, for example, a laser light source. The light source 21 is, for example, a pulse laser. A central wavelength, a pulse width, and a repetition period of light emitted from the light source 21 are not particularly limited. The center wavelength of the light emitted from the light source 21 is, for example, 300 nm or more and 2000 nm or less. A spot diameter of the light emitted from the light source 21 on the surface of the magnetic metamaterial 10 is made equal to the size of the magnetic metamaterial 10. The spot diameter of light is, for example, 250 μm

The optical element 22 is, for example, a polarizer or a wave plate. The light emitted from the light source 21 passes through the optical element 22, thereby changing its polarization state. The magnetic metamaterial 10 is irradiated with the light whose polarization state is controlled by the optical element 22.

The light with which the magnetic metamaterial 10 is irradiated is, for example, elliptically polarized light whose ellipticity angle ε_{ω} and azimuth angle θ_{ω} are controlled. Linearly polarized light corresponds to the case where the ellipticity angle ε_{ω} is 0° or 90° and is a mode of elliptically polarized light. Circularly polarized light corresponds to the case where the ellipticity angle ε_{ω} is 45° and is a mode of elliptically polarized light. Ellipticity is the ratio of the length a of a major axis to the length b of a minor axis of elliptically polarized light and is represented by b/a. The ellipticity angle ε_{ω} is represented by tan ε_{ω}=b/a. The azimuth angle θ_{ω} is the angle between the major axis of the elliptically polarized light and the y axis. The y axis is, for example, the transmission axis of incident linearly polarized light.

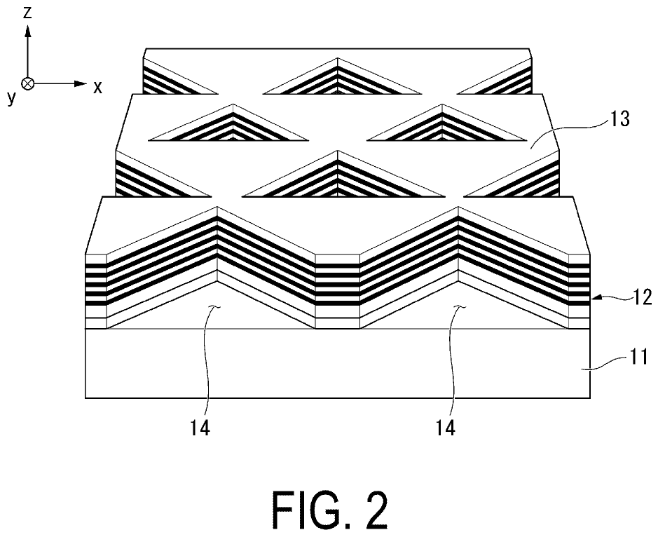

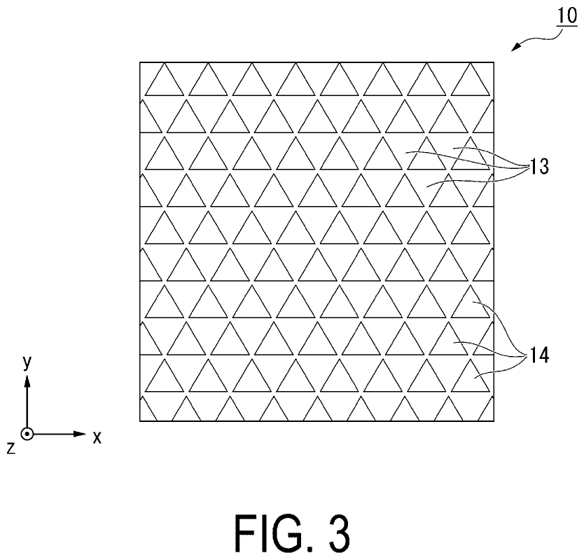

FIG. 2 is a perspective view of the magnetic metamaterial 10. FIG. 3 is a plan view of the magnetic metamaterial 10. The magnetic metamaterial 10 has broken space inversion symmetry and time reversal symmetry. The magnetic metamaterial 10 includes, for example, a substrate 11 and a perpendicularly magnetized film 12 layered on the substrate 11.

The substrate 11 is not particularly limited. The substrate 11 is, for example, quartz glass. Another layer may be provided between the substrate 11 and the perpendicularly magnetized film 12. For example, an adhesion layer may be formed between the substrate 11 and the perpendicularly magnetized film 12 to improve the adhesion between the substrate 11 and the perpendicularly magnetized film 12. The adhesion layer is, for example, silicon nitride. For example, a base layer may also be formed between the substrate 11 and the perpendicularly magnetized film 12 to improve the crystallinity of the perpendicularly magnetized film 12. The base layer is, for example, platinum.

The perpendicularly magnetized film 12 is a magnetic film having an axis of easy magnetization in a direction intersecting (perpendicular to) the vy plane. The magnetic film may be a ferromagnetic film or a ferrimagnetic film. The magnetic film has broken time reversal symmetry. This is because, in a magnetically ordered state, the magnetic moment created by the angular momentum of the spin or orbit is reversed by the time reversal operation. The magnetic film is preferably a ferromagnetic film, for example.

The perpendicularly magnetized film 12 is isotropic with respect to light before unit structures are formed. Being isotropic with respect to light means a characteristic that the perpendicularly magnetized film 12 responds in the same way no matter which direction the perpendicularly magnetized film 12 is irradiated with light.

The perpendicularly magnetized film 12 is, for example, a multilayer film of a 3d transition metal and a noble metal, a sandwich film, an L10 type or L11 type ordered alloy, or a rare earth-transition metal amorphous alloy. Examples of the multilayer film of a 3d transition metal and a noble metal include a multilayer film of Co and Pt, a multilayer film of Co and Pd, a multilayer film of Co and Au, and a multilayer film of Fe and Pt. The sandwich film is, for example, a film in which CoFeB is sandwiched between MgO and Ta or a film in which Co is sandwiched between Ta and Pt. The L10 type or L11 type ordered alloy includes FePt, FePd, CoPt, MnGa, MnAl, or the like. The rare earth-transition metal amorphous alloy is, for example, GdFeCo. The multilayer film of a 3d transition metal and a noble metal is particularly preferred because it has both high corrosion resistance and high perpendicular magnetic anisotropy and can be formed at room temperature.

The perpendicularly magnetized film 12 has a plurality of unit structures 13. The plurality of unit structures 13 are formed in the perpendicularly magnetized film 12 that is isotropic to light before the unit structures are formed. The plurality of unit structures 13 are periodically arranged in in-plane directions of the magnetic metamaterial 10. The plurality of unit structures 13 are periodically arranged, for example, in one of the in-plane directions of the magnetic metamaterial 10. The plurality of unit structures 13 may also be periodically arranged, for example, in different in-plane directions of the magnetic metamaterial 10. The plurality of unit structures 13 are formed, for example, by a plurality of openings 14. The arrangement state of the plurality of unit structures 13 is not particularly limited. For example, lines connecting the centers of gravity of adjacent unit structures 13 may form a triangle or another polygon.

The size of each unit structure 13 is equal to or less than the wavelength of the irradiated light. The size of each unit structure 13 is, for example, 1 μm or less. The size of each unit structure 13 is a maximum width in the x direction and a maximum width in the y direction of the unit structure 13.

Each unit structure 13 has three-fold rotational symmetry. Each opening 14 also has three-fold rotational symmetry. Three-fold rotational symmetry means that when the unit structure 13 is rotated by +120°, the structure will be the same as before the rotation. In the perpendicularly magnetized film 12, the unit structures 13 have three-fold rotational symmetry and thus the space inversion symmetry is broken. The space inversion symmetry is point symmetry and means that when the coordinates (x, y, z) are inverted to (−x, −y, −z), the structure will be the same as before the inversion

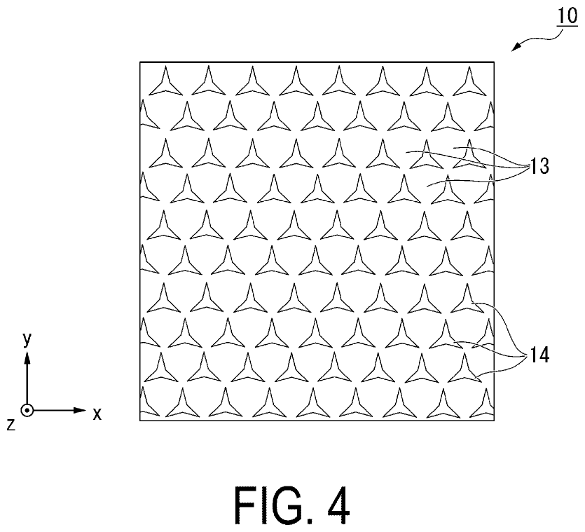

The planar shape of each unit structure 13 viewed in the z direction is, for example, an equilateral triangle whose corners are shared with adjacent unit structures 13. The planar shape of each opening 14 viewed in the z direction is, for example, an equilateral triangle. The planar shapes of the unit structures 13 and the openings 14 are not particularly limited as long as they each have three-fold rotational symmetry. For example, the relationship between the unit structures 13 and the openings 14 may be reversed or the openings 14 may each be in the three diamonds shape as shown in FIG. 4.

The unit structure 13 and the opening 14 belong to the 3m point group. Their planar periodic structures belong to the p3m1 space group.

The magnetic metamaterial 10 is obtained by processing a formed perpendicularly magnetized film into unit structures.

First, a perpendicularly magnetized film is formed on a substrate 11. The perpendicularly magnetized film can be formed by a known method such as sputtering or chemical vapor deposition (CVD). For example, when the perpendicularly magnetized film is a multilayer film of a 3d transition metal and a noble metal, the 3d transition metal and the noble metal are alternately deposited. An adhesion layer and a base layer may also be formed between the substrate 11 and the perpendicularly magnetized film.

Next, openings 14 having three-fold rotational symmetry are formed in the formed perpendicularly magnetized film. The openings 14 can be formed, for example, by electron beam lithography.

The spin current control apparatus 100 according to the first embodiment can control the direction and magnitude of a spin current generated on the surface of the magnetic metamaterial 10 by irradiating the magnetic metamaterial 10 with light whose ellipticity angle ε_{ω} and azimuth angle θ_{ω} are controlled. That is, the spin current control method according to the present embodiment can control the spin current by irradiating the magnetic metamaterial with light whose ellipticity angle ε_{ω} and azimuth angle θ_{ω} are controlled.

When a material having no space inversion symmetry is irradiated with light, an electric current is generated due to photoexcitation without an external field. This phenomenon is called the photogalvanic effect. A phenomenon similar to this is the magneto-photogalvanic effect. The magneto-photogalvanic effect is a phenomenon in which a spin current is generated by photoexcitation without an external field when a material having neither space inversion symmetry nor time reversal symmetry is irradiated with light.

The magneto-photogalvanic effect is a second-order nonlinear optical effect and is expressed by the following relational expression (1).

$$\begin{matrix}[ Math . 1 ] & \\ {J}_{i} = {β}_{ijk} ( 0 ; ω , - ω ) {E}_{j} ( ω ) {E}_{k}^{*} ( ω ) & ( 1 )\end{matrix}$$

In this expression, Eⱼ(ω) and Eₖ*(ω)=Eₖ(−_{ω}) denote a j-polarized electric field and a k-polarized electric field of the incident light at ω, respectively, and induce a zero-bias photocurrent in the i direction proportional to the square of the alternating electric field. βᵢⱼₖ is a third-rank polar tensor whose sign is changed by space inversion and time reversal operations and whose value is determined by the symmetry of the material.

The magnetic metamaterial 10 is a perpendicularly magnetized film having three-fold rotational symmetry, and when irradiated with light whose ellipticity angle ε_{ω} and azimuth angle θ_{ω} are controlled, generates a spin current Jₛ based on the above expression. The following relational expressions (2) and (3) are derived because the magnetic metamaterial 10 belongs to the 3m point group as described above.

$$\begin{matrix}[ Math . 2 ] & \\ \vert {J}_{s} \vert ∝ cos 2 {ε}_{ω} & ( 2 )\end{matrix}$$

$$\begin{matrix}[ Math . 3 ] & \\ {θ}_{s} = - 2 {θ}_{ω} ∓ 90 ° & ( 3 )\end{matrix}$$

|Jₛ| indicates the magnitude of the spin current and is proportional to cos 2ε_{ω}. That is, the magnitude of the spin current is influenced by the ellipticity angle ε_{ω}. Namely, the magnitude of the spin current can be controlled by controlling the ellipticity angle ε_{ω}. θₛ corresponds to a main direction in which the spin current is generated and is the angle between the y axis and the main direction of the spin current. The direction in which the spin current is generated is influenced by the azimuth angle θ_{ω}. Namely, the direction in which the spin current is generated can be controlled by controlling the azimuth angle θ_{ω}.

The above relationships are obtained when the magnetic metamaterial 10 is applied to the symmetry of the 3m point group, and the magnitude and direction of the spin current can be controlled when the magnetic metamaterial 10 has three-fold rotational symmetry.

Spin currents are applied to magnetic memories, thermoelectric conversion elements, oscillators, sensors, and the like. If the direction of spin currents can be controlled, it may be possible, for example, to impart directionality to signals. The spin current control apparatus 100 can be applied to new spintronics devices.

When a nonmagnetic (for example, Pt) metamaterial having no space inversion symmetry is irradiated with light, a photocurrent is generated due to the photogalvanic effect. The photocurrent can be converted into a spin current using the spin Hall effect. The spin Hall effect is a phenomenon in which, when an electric current flows in one direction, a spin current is generated in a direction perpendicular to the direction in which the electric current flows. That is, it is also possible to obtain a spin current by irradiating a nonmagnetic metamaterial having no space inversion symmetry with light. However, the efficiency of conversion from the photocurrent to the spin current is not sufficient and it is difficult to obtain a spin current that is applicable for use in measurement and devices. The spin current control apparatus 100 according to the first embodiment can control a spin current of sufficient magnitude by light because it directly controls and detects the spin current by the magneto-photogalvanic effect.

The above exemplifies an embodiment of the spin current control apparatus 100. However, the present invention is not limited to the present embodiment.

### EXAMPLES

### First Example

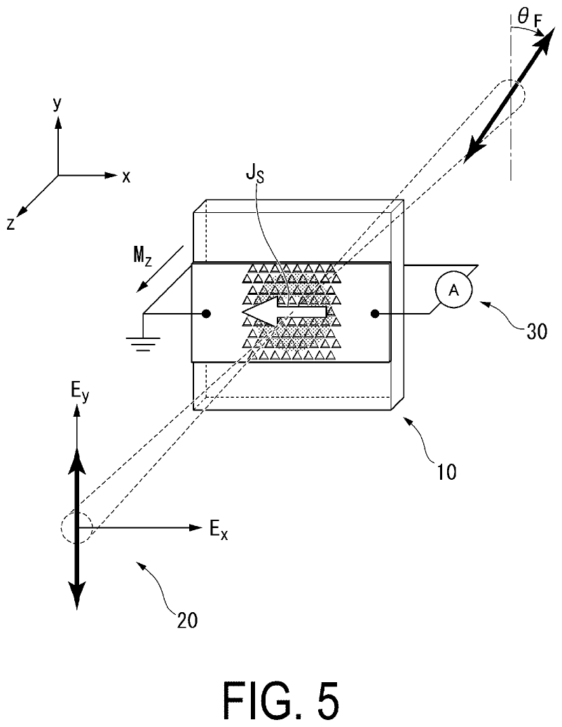

FIG. 5 is an image diagram of an experimental system according to a first example. The experimental system of the first example includes a magnetic metamaterial 10, a light irradiation unit 20, a measurement system 30, and a magnetic field generation unit (not illustrated). Experiments were conducted at room temperature.

A specific configuration of the magnetic metamaterial 10 is the same as the configuration shown in FIGS. 2 and 3. The magnetic metamaterial 10 includes a SiO₂ substrate which has been polished on both sides and a perpendicularly magnetized film in which equilateral triangular openings having three-fold rotational symmetry are periodically formed. Between the SiO₂ substrate and the perpendicularly magnetized film, there are an adhesion layer (of SiN with a thickness of 5 nm) and a base layer (of Pt with a thickness of 2 nm) in order from the SiO₂ substrate side and equilateral triangular openings are periodically formed in these layers as well. The perpendicularly magnetized film is a multilayer film in which layers of Pt with a thickness of 0.9 nm and Co with a thickness of 0.5 nm are alternately layered. The numbers of layered Pt layers and Co layers were each five. The perpendicularly magnetized film has magnetization M_{z} in the z direction. There is a cap layer (of Pt with a thickness of 2 nm) on the perpendicularly magnetized film and equilateral triangular openings are periodically formed in the cap layer as well. Each layer is formed by high frequency sputtering.

The equilateral triangular openings are formed in an area of 250 μm×250 μm by electron beam lithography. Etching was performed using Ar ions after the openings were formed. One side of each opening is 480 nm, and the openings are periodically arranged at intervals of 558 nm. The light irradiation unit 20 includes a Ti:sapphire laser (Spectra-Physics, Mai Tai (trade name)). The laser light used had a center wavelength of 800 nm, a pulse width of 100 fs, and a repetition period of 80 MHz. The spot diameter of the laser light on the surface of the magnetic metamaterial 10 was 250 μm. The laser light that has passed through the magnetic metamaterial 10 was monitored with a CCD camera. The laser light was adjusted such that it irradiated the center of the magnetic metamaterial 10 in order to eliminate the influence of the Seebeck effect and the Nernst effect. The intensity of the laser light was modulated with 1 kHz by an optical chopper. The light with which the magnetic metamaterial 10 was irradiated was linearly polarized light having an ellipticity angle ε_{ω} and an azimuth angle θ_{ω} of 0°.

When the magnetic metamaterial 10 is irradiated with light, a spin current is generated on the surface of the magnetic metamaterial 10. The spin current was measured separately in the x and y directions with a two-phase lock-in amplifier (Stanford Research Systems, SR865) using a reference signal from the optical chopper. The spin current was obtained by time averaging. The magnitude of the spin current |Jₛ| was calculated as |Jₛ|=((J_{s,y})²+(J_{s,x})²)^{1/2}. J_{s,y} is a component of the spin current in the y direction and J_{s,x} is a component of the spin current in the x direction. The direction θₛ in which the spin current is generated was obtained using θₛ=tan⁻¹ (J_{s,x}/J_{s,y}).

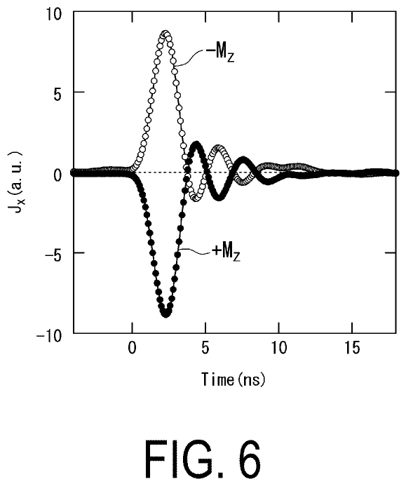

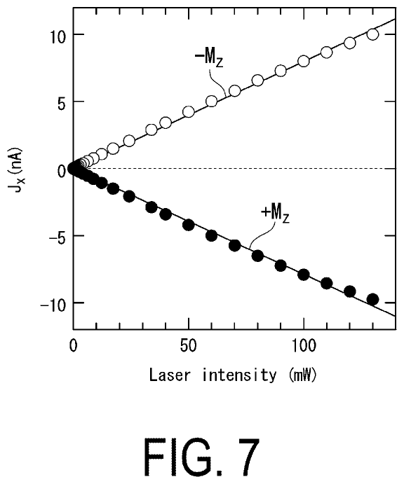

FIG. 6 shows the response characteristics of a spin current generated after the magnetic metamaterial 10 was irradiated with laser light in the first example. FIG. 7 shows the results of changing the intensity of the laser light with which the magnetic metamaterial 10 was irradiated in the first example.

As shown in FIG. 6, a spin current is generated about 2 nsec after the magnetic metamaterial 10 is irradiated with laser light. That is, the spin current control apparatus shown in the first example has fast response characteristics. Although it takes 2 nsec to detect the spin current in FIG. 6, this time depends on the spin current measurement system and in principle it is conceivable that the respond time is on the order of femto seconds. The magnitude of the spin current increases as the intensity of the laser light increases as shown in FIG. 7.

FIGS. 6 and 7 commonly show that when the direction of the magnetization of the perpendicularly magnetized film is reversed, the direction in which the spin current is generated is reversed. In FIGS. 6 and 7, +M_{z} indicates the case where the magnetization of the perpendicularly magnetized film is oriented in a +z direction and −M_{z} indicates the case where the magnetization of the perpendicularly magnetized film is oriented in a −z direction. The +z direction is the direction from the magnetic metamaterial 10 to the light irradiation unit 20 and the −z direction is the direction from the light irradiation unit 20 to the magnetic metamaterial 10. The orientation direction of the magnetization of the perpendicularly magnetized film was changed by applying a magnetic field to the magnetic metamaterial 10 by a magnetic field generation unit (not illustrated).

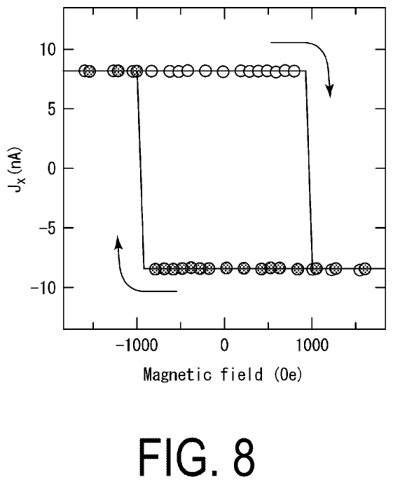

FIG. 8 shows the results of measuring the influence on the spin current when changing the magnetic field applied to the magnetic metamaterial 10 in the first example. The spin current formed a hysteresis loop with respect to an external magnetic field as shown in FIG. 8. Even when the absolute value of the external magnetic field applied to the perpendicularly magnetized film was increased up to about 1000 Oe, the magnitude and direction of the spin current did not change, but when it exceeded 1000 Oe, the direction of the spin current was reversed.

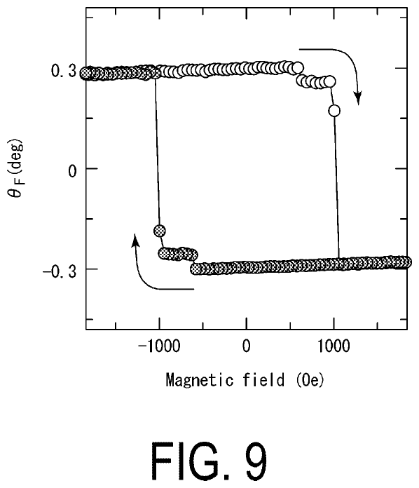

FIG. 9 shows the results of measuring the direction of magnetization of the perpendicularly magnetized film using the Faraday effect in the first example. Light with which the perpendicularly magnetized film is irradiated rotates after passing through the perpendicularly magnetized film due to the Faraday effect. The Faraday rotation angle θ_{F} was measured by a balance detection method. When the magnetization direction of the perpendicularly magnetized film is reversed, the Faraday rotation angle θ_{F} is reversed as shown in FIG. 9. That is, it can be said that when the magnitude of the external magnetic field exceeds 1000 Oe, the magnetization direction of the perpendicularly magnetized film is reversed. The direction in which the spin current is generated is reversed because the orientation direction of the magnetization of the perpendicularly magnetized film is reversed as can be seen from FIGS. 8 and 9.

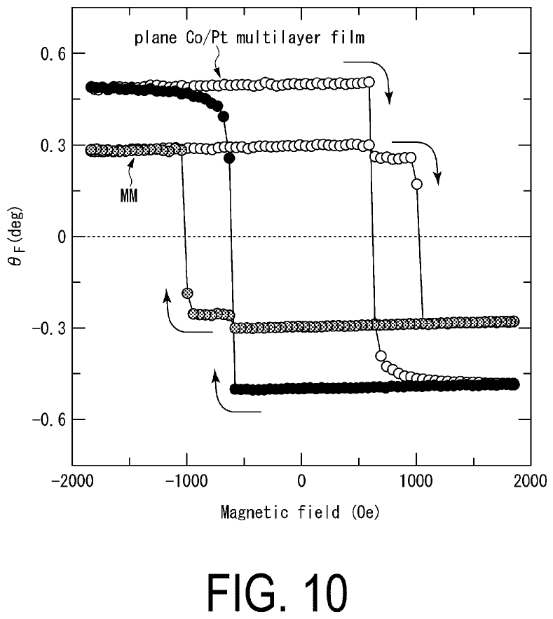

FIG. 10 is a diagram comparing a magnetization curve of a plane Co/Pt multilayer film in which a plurality of openings had not yet been formed with a magnetization curve of the magnetic metamaterial (MM). The coercive force Hc (Hc≈1000 Oe) of the magnetic metamaterial was larger than the coercive force Hc′ (Hc′≈600 Oe) of the Co/Pt multilayer film formed in a plane as shown in FIG. 10. This is thought to be because magnetization reversal was prevented by the openings in the magnetic metamaterial.

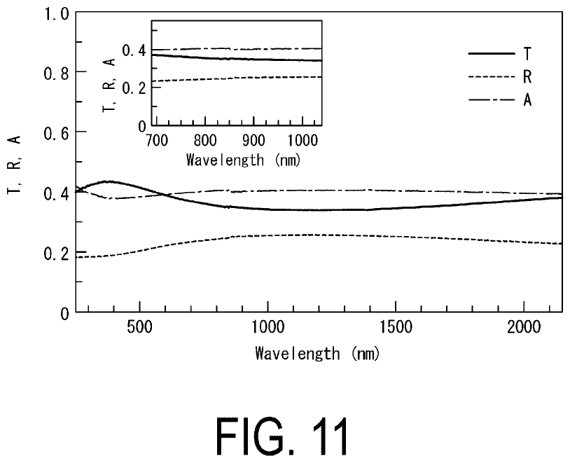

FIG. 1l shows the results of measuring the wavelength dependence of the transmittance (T), reflectance (R), and absorption (A) of the magnetic metamaterial. The absorption (A) was obtained by J−transmittance (T)−reflectance (R). The magnetic metamaterial has little dependence on the wavelength of light as shown in FIG. 11.

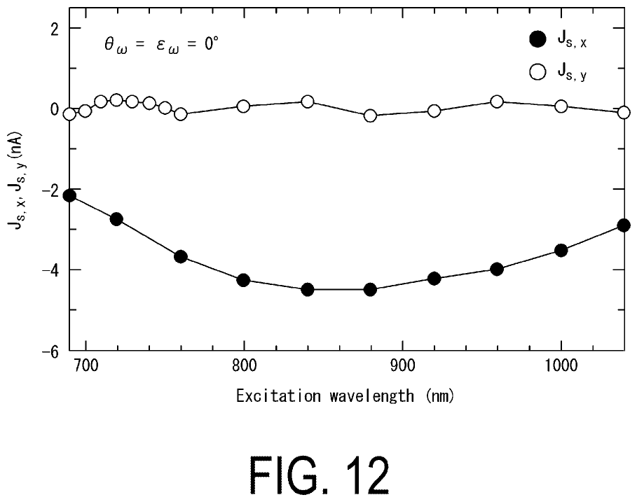

FIG. 12 shows the results of measuring the dependence of the magnitude of the spin current on the wavelength of the irradiated light in the experimental system of the first example. Even when the irradiation wavelength was changed, a spin current (J_{s,y}) was not generated in the y direction, but a spin current (J_{s,x}) was generated only in the x direction. That is, the relationship that a spin current was generated only in the x direction when the magnetic metamaterial was irradiated with linearly polarized light having an ellipticity angle c and an azimuth angle θ_{ω} of 0° did not change.

### Second Example

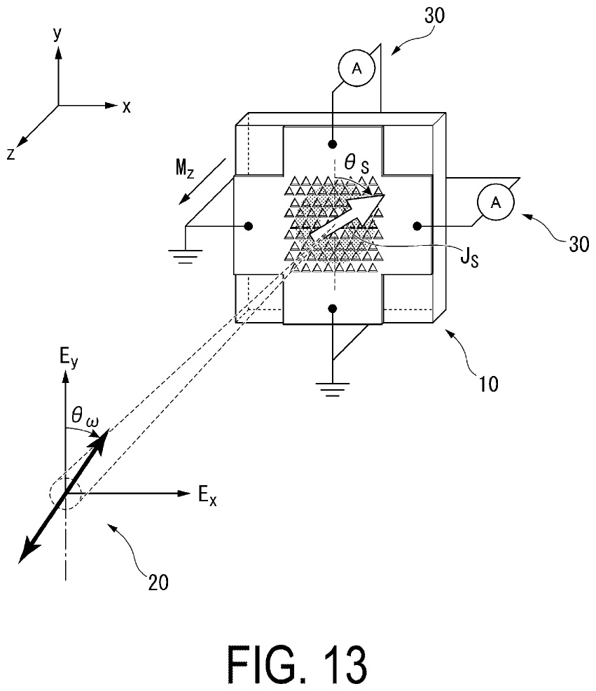

FIG. 13 is an image diagram of an experimental system according to a second example. The experimental system of the second example is the same as the experimental system of the first example in that the magnetic metamaterial 10 is irradiated with light from the light irradiation unit 20 and a spin current generated on the surface of the magnetic metamaterial 10 is measured by the measurement system 30. On the other hand, the second example differs from the first example in that the azimuth angle θ_{ω} of the light with which the magnetic metamaterial 10 is irradiated is changed.

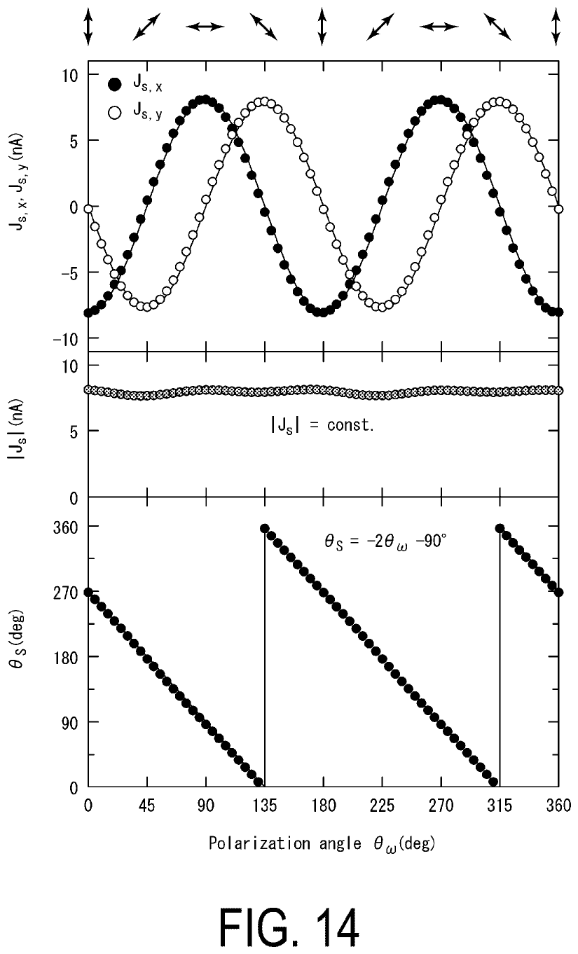

FIG. 14 shows the results of changing the azimuth angle θ_{ω} of light with which the magnetic metamaterial 10 was irradiated in the experimental system according to the second example. The vertical axis of a graph shown in FIG. 14 represents, from the top, the x and y components of the magnitude of the spin current (J_{s,x}, J_{s,y}), the magnitude of the spin current (|Jₛ|), and the direction θₛ in which the spin current was generated. The horizontal axis of the graph shown in FIG. 14 is the azimuth angle θ_{ω}.

The magnitude of the spin current (|Jₛ|) did not change when the azimuth angle θ_{ω} was changed, but the direction θₛ in which the spin current was generated changed continuously when the azimuth angle θ_{ω} was changed as shown in FIG. 14. The results show relational expressions (2) and (3). According to relational expression (2), the magnitude of the spin current (|Jₛ|) is not affected by the azimuth angle θ_{ω}, which agreed with the actual experimental results. According to relational expression (3), the direction θₛ in which the spin current is generated is proportional to the azimuth angle θ_{ω}, which agreed with the actual experimental results.

### Third Example

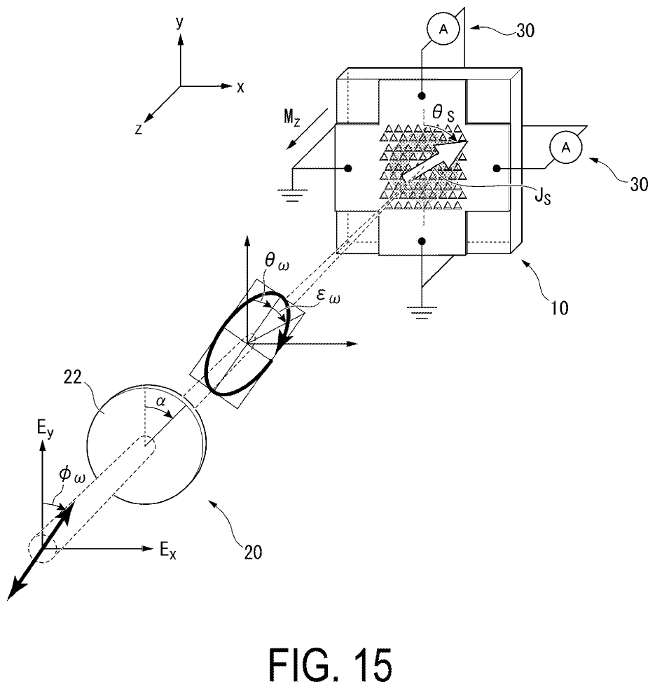

FIG. 15 is an image diagram of an experimental system according to a third example. The experimental system of the third example is the same as the experimental system of the first example in that the magnetic metamaterial 10 is irradiated with light from the light irradiation unit 20 and a spin current generated on the surface of the magnetic metamaterial 10 is measured by the measurement system 30. On the other hand, the third example differs from the first example in that the ellipticity angle ε_{ω} and the azimuth angle θ_{ω} of the light with which the magnetic metamaterial 10 is irradiated are changed. The ellipticity angle ε_{ω} and the azimuth angle θ_{ω} were changed by inserting an optical element 22 into the optical path. A quarter-wave plate was used as the optical element 22. The azimuth angle φ_{ω} of the light with which the optical element 22 was irradiated was also changed.

Experiments were conducted with the rotation angle α of the quarter-wave plate being 0° and 45°. The ellipticity angle ε_{ω} and the azimuth angle θ_{ω} of the excitation light are determined by the azimuth angle θ_{ω} and the rotation angle α of the light with which the optical element 22 is irradiated. When the rotation angle α is 0°, the azimuth angle θ_{ω} is 0° or 90°. The ellipticity angle ε_{ω} changes continuously from −45° to 45°. When the rotation angle α is 45°, the azimuth angle θ_{ω} is 45° or 135°. The ellipticity angle ε_{ω} changes continuously from −45° to 45°.

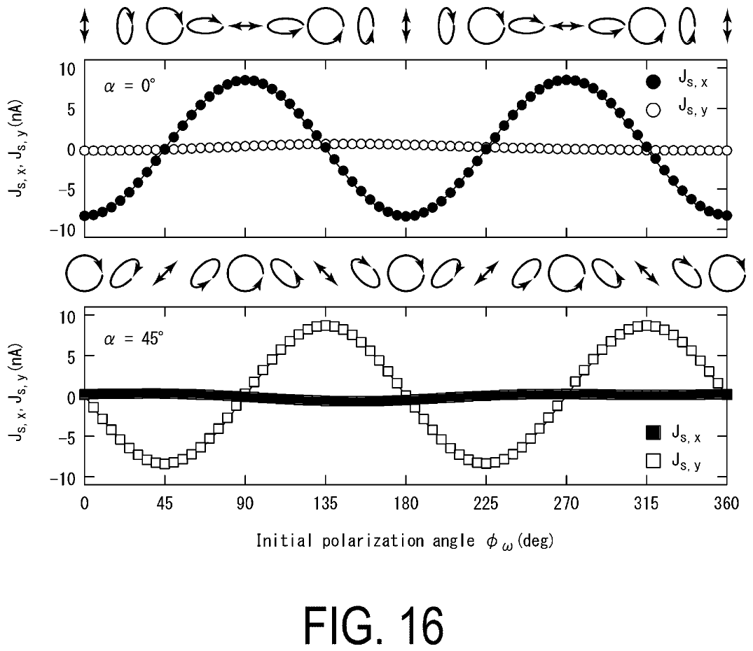

FIG. 16 shows the results of measuring the x and y components (J_{s,x}, J_{s,y}) of the magnitude of the spin current when changing the azimuth angle φ_{ω} of light with which the optical element 22 was irradiated in the experimental system according to the third example. The upper diagram in FIG. 16 shows the results when the rotation angle α is 0° and the lower diagram in FIG. 16 shows the results when the rotation angle α is 45°.

When the rotation angle α is 0°, the x component (J_{s,x}) of the magnitude of the spin current shows the relationship of −cos 2φ_{ω}. When the rotation angle α is 0°, the y component (J_{s,y}) of the magnitude of the spin current remains constant at zero. On the other hand, when the rotation angle & is 45°, the y component (J_{s,y}) of the magnitude of the spin current shows the relationship of −sin 2φ_{ω}. When the rotation angle α is 45°, the x component (J_{s,x}) of the magnitude of the spin current remains constant at zero.

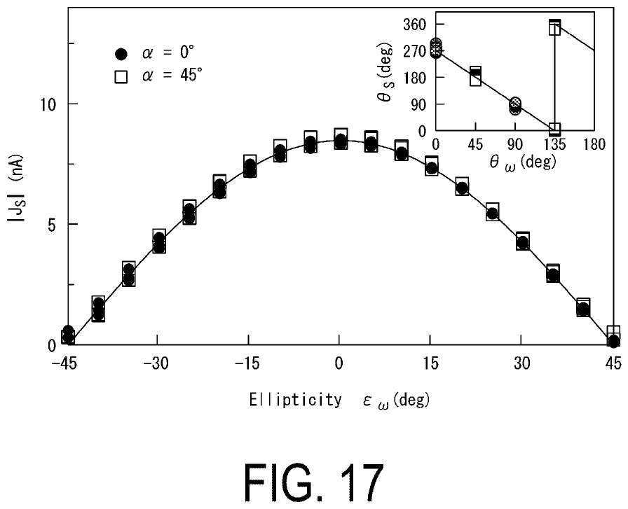

FIG. 17 is a diagram obtained by replacing the results of FIG. 16 with the relationship between the ellipticity angle ε_{ω} and the magnitude (|Jₛ|) of the spin current. The magnitude of the spin current is proportional to cos 2ε_{ω} as shown in FIG. 17. This relationship agrees with relational expression (2).

### REFERENCE SIGNS LIST

10 Magnetic metamaterial
11 Substrate
12 Perpendicularly magnetized film
13 Unit structure
14 Opening
20 Light irradiation unit
21 Light source
22 Optical element
30 Measurement system
100 Spin current control apparatus

1. A magnetic metamaterial comprising
a perpendicularly magnetized film that is isotropic with respect to light,
wherein the perpendicularly magnetized film has a plurality of unit structures periodically arranged in an in-plane direction, and
wherein each of the plurality of unit structures has a size equal to or less than a wavelength of irradiated light and has three-fold rotational symmetry.

2. The magnetic metamaterial according to claim 1, wherein the perpendicularly magnetized film has a plurality of openings forming the plurality of unit structures.

3. The magnetic metamaterial according to claim 2, wherein each of the plurality of openings is equilaterally triangular.

4. A spin current control apparatus comprising:
the magnetic metamaterial according to claim 1; and
a light irradiation unit configured to irradiate the magnetic metamaterial with light,
wherein the light irradiation unit is configured to control an ellipticity angle and an azimuth angle of light irradiating the magnetic metamaterial.

5. A method of controlling a spin current, the method comprising
irradiating a magnetic metamaterial with light whose ellipticity angle and azimuth angle are controlled,
wherein the magnetic metamaterial includes a perpendicularly magnetized film that is isotropic with respect to light,
wherein the perpendicularly magnetized film has a plurality of unit structures periodically arranged in an in-plane direction, and
wherein each of the plurality of unit structures has a size equal to or less than a wavelength of irradiated light and has three-fold rotational symmetry.
